(19) United States
(12) Patent Application Publication
(10) Pub. No.: US 2011/0060959 A1
(43) Pub. Date: Mar. 10, 2011

(54) Method and Apparatus for Data Receiving

(75) Inventors: Jin Xu, Shenzhen City (CN); Jun Xu, Shenzhen City (CN); Song Li, Shenzhen City (CN); Zhifeng Yuan, Shenzhen City (CN); Liujun Hu, Shenzhen City (CN)

(73) Assignee: ZTE CORPORATION, Shenzhen City (CN)

(21) Appl. No.: 12/991,045

(22) PCT Filed: Oct. 14, 2008
(86) PCT No.: PCT/CN2008/072679

§ 371 Date: Nov. 4, 2010

(30) Foreign Application Priority Data
May 7, 2008 (CN) 200810094678.5

(51) Int. Cl. H03M 13/05; G06F 11/10

(52) U.S. Cl. 714/752; 714/E11.032

(57) ABSTRACT

A method and apparatus for receiving data is provided. A data receiving terminal processes each received file block as follows: performing forward error correction decoding for Tb bit sequences to be decoded of the file block respectively, obtaining Tb decoded information bit sequences with a length of K, wherein, the i^{th} bit sequence to be decoded is composed of the i^{th} bits of each unerased information file segment and check file segment of the file block in sequence according to the sequence of the information file segments and the check file segments; combing K decoded information file segments of the file block in sequence to generate original file data of the file block, wherein the M^{th} decoded information file segment is composed of the M^{th} bits of the Tb decoded information bit sequences in sequence according to the sequence of the information bit sequences.

### TECHNICAL FIELD

The present invention relates to a method and apparatus for receiving data.

### BACKGROUND ART

Data are divided into data packets for transmission in network/communication channels. Network protocolor coding is generally used to provide error correcting mechanism in order to improve reliability of data transmission. For example, when data are transmitted on the internet, Transmission Control Protocol (TCP) should be used to provide error detection and retransmission mechanism so as to transmit data reliably, i.e., a transmitting terminal is informed to retransmit data when loss of data packets has been detected.

However, a receiving terminal is not allowed to feed back loss of data packets and error information to a transmitting terminal when data are transmitted in multimedia broadcasting channels since unidirectional channels are used and data are transmitted in a one-to-many broadcast/multicast manner, therefore, the above error detection and retransmission mechanism cannot be used. In this case, Forward Error Correction (FEC) encoding needs to be performed for data packets before transmission. A typical application layer FEC comprises RS (Reed-Solomon) codes and digital Fountain codes and the like. Encoding and decoding of RS codes are rather complex, and generally the above FEC encoding only applies in cases of short code length. LT (Luby Transform) codes and Raptor codes are two kinds of digital Fountain codes that can be practically used. LT codes have linear encoding and decoding times, and is substantially improved relative to RS codes; while Raptor codes have higher decoding efficiency due to use of pre-encoding technique. Raptor codes of Digital Fountain, Inc. are used in both Multimedia Broadcast/Multicast Service (MBMS) and Digital Video Broadcasting (DVB) of 3GPP (3rd Generation Partnership Project) as their FEC coding solution.

If the first K bits of a code word after encoding are the same with the information bits, then the codes are called as system codes. The process of encoding is a process of generating a code length of N bits from K information bits, and N-K check bits are added to achieve the purpose of error detection and correction. LT codes do not support the encoding manner of system codes and thus can hardly meet some practical FEC encoding requirements; Raptor codes support system codes, but a separate pre-encoding process is required, i.e., a pre-encoding matrix is required, therefore, the complexity of encoding is very high.

Due to the above drawbacks of the encoding methods, LDGC (Low Density Generator Matrix Codes) is incorporated. LDGC is a kind of linear block codes, and the non-zero elements in its generator matrix (encoding matrix) are generally sparse, meanwhile, LDGC are also a kind of system codes.

FIG. 1 illustrates a generator matrix of LDGC. As shown in FIG. 1, a square matrix corresponding the first L lines in the transposed G_{ldgc}^{T} of the generator matrix of LDGC is generally an upper or lower triangular matrix, the inversion of which may be achieved by way of iteration. Wherein, x and y in FIG. 1 can be 0.

FIG. 2 is an illustration of performing corresponding erasion for the generator matrix of LDGC during decoding according to the erasion state of received code words.

As shown in FIG. 2, if an error arises (which is called as data erased) when data are transmitted, the receiving terminal needs to perform corresponding erasion operation on the G_{ldgc}^{T} before decoding using G_{ldgc}^{T}. That is to say, it is assumed that the symbols of {rᵢ, rᵢ₊₁, . . . , r_{i+X1}} and {rⱼ, rⱼ₊₁, . . . , r_{j+X2}} in the sequence R (r₀, r₁, . . . r_{N-1}) with a length of N bits are erased by channels, then the {i, i+1, . . . i+X1}-^{th} line and the {j, j+1, . . . j+X2}-^{th} line in G_{ldgc}^{T} should also be erased, obtaining an erasion generator matrix Gₑ. It is noted that Gₑ is the same for the same data loss/error conditions.

In the prior art, when FEC encoding and decoding methods of LDGC and the like are used for data transmission, a transmitting terminal performs FEC encoding on the data packets, a receiving terminal generates a corresponding erasion generator matrix Gₑ according to the transmission state of each data packet and decodes the data packets using the Gₑ. The efficiency of this method for receiving data is very low, and decoding cannot be efficiently performed and the entire dada packet has to be discarded when there are too many data errors in the data packet, therefore, the efficiency of data transmission is greatly decreased when conditions of networks/channels are relatively bad.

### SUMMARY OF INVENTION

The present invention provides a method and apparatus for receiving data with an improved efficiency of data transmission and increased processing speed of data decoding and the like in order to overcome the defects of the prior art.

In order to solve the above problem, the present invention provides a method for receiving data, comprising a data receiving terminal processing each received file block as follows:

A: performing forward error correction decoding for Tb bit sequences to be decoded of the file block respectively, obtaining Tb decoded information bit sequences with a length of K;

wherein, the i^{th} bit sequence to bed ecoded is composed of the i^{th} bits of each unerased information file segment and check file segment of the file block in sequence according to a sequence of the information file segments and the check file segments;

B: combing K decoded information file segments of the file block in sequence to generate original file data of the file block;

wherein the m^{th} decoded information file segment is composed of the m^{th} bits of the Tb decoded information bit sequences in sequence according to a sequence of the information bit sequences;

i=1, . . . , Tb; m=1, . . . , K; a length of the information file segment and check file segment is Tb bits.

Additionally, the data receiving terminal obtains the unerased information file segments and check file segments from transmission packets; the transmission packets comprise file segment indexes; a file segment index corresponding to an information file segment is lower than a file segment index corresponding to a check file segment in a same file block; and

the data receiving terminal determines the sequence of the information file segments and the check file segments according to the file segment indexes.

Additionally, the transmission packets further comprise file block indexes;

the method further comprises the following step after completing processing of the file block:

C: the data receiving terminal combining original file data of each file block in sequence according to the file block indexes to generate the original file data.

Additionally, if F/T is not an integer, the data receiving terminal deletes P filling bits from a last file segment of a last file block;

wherein, P=8×(T×Kₜ−F); F is a total byte length of said data, Kₜ=┌F/T┐, and T=Tb/8.

Additionally, the forward error correction decoding uses LDGC algorithm, and the method further comprises the following step prior to performing said forward error correction decoding:

A1: the data receiving terminal deleting corresponding lines of transposed G_{ldgc}^{T} of a LDGC generator matrix to generate Gₑ according to file segment indexes of erased information file segments and check file segments in the file block;

wherein in step A, said forward error correction decoding is performed for the bit sequences to be decoded by using the Gₑ.

The present invention further comprises an apparatus for receiving data, comprising a receiving unit, a decoding unit and a data combining unit; wherein:

the receiving unit is used for outputting Tb bit sequences to be decoded a file block; wherein the i^{th} bit sequence to be decoded is composed of the i^{th} bits of each unerased information file segment and check file segment of the file block in sequence according to a sequence of the information file segments and the check file segments;

the decoding unit is used for performing forward error correction decoding for the Tb bit sequences to be decoded of the file block output by the receiving unit respectively, outputting Tb decoded information bit sequences with a length of K;

the data combining unit is used for combining K decoded information file segments of the file block in sequence to generate original file data of the file block; wherein the m^{th} decoded information file segment is composed of the m^{th} bits of the Tb decoded information bit sequences in sequence according to a sequence of the information bit sequences;

i=1, . . . , Tb; m=1, . . . , K; a length of the information file segment and check file segment is Tb bits.

the receiving unit obtains the unerased information file segments and check file segments from transmission packets; the transmission packets comprise file segment indexes; a file segment index corresponding to an information file segment is lower than a file segment index corresponding to a check file segment in a same file block;

the receiving unit determines the sequence of the information file segments and the check file segments according to the file segment indexes.

Additionally, the transmission packets further comprise file block indexes;

the data combining unit is also used for combining original file data of each file block in sequence according to the file block indexes to generate the original file data.

Additionally, if F/T is not an integer, the data combining unit is also used for deleting P filling bits from a last file segment of a last file block;

wherein, P=8×(T×Kₜ−F); F is a total byte length of said data, Kₜ=┌F/T┐, and T=Tb/8.

Additionally, the forward error correction decoding uses LDGC algorithm;

the decoding unit also deletes corresponding lines of transposed G_{ldgc}^{T} of a LDGC generator matrix to generate Gₑ according to file segment indexes of erased information file segments and check file segments in the file block prior to performing said forward error correction decoding; and uses the Gₑ to perform the forward error correction decoding is performed for the bit sequences to be decoded.

In a word, the workload of the receiving terminal can be greatly reduced by using the data transmission method and the corresponding decoding method and apparatus of the present invention; additionally, since loss of a single data packet/information file segment does not cause loss (erasion) of a large amount of information of code words at the receiving terminal, the success rate success rate of decoding and the reliability of data transmission are dramatically improved.

### BRIEF DESCRIPTION OF DRAWINGS

FIG. 1 illustrates a generator matrix of LDGC;

FIG. 2 is an illustration of performing corresponding erasion for the generator matrix of LDGC during decoding according to the erasion state of received code words;

FIG. 3 illustrates the flow of a data transmission method;

FIG. 4 is an illustration of performing FEC encoding for each information file segment in a file block;

FIG. 5 illustrates the structure of a transmission packet according to the present invention;

FIG. 6 illustrates of low of a data transmission method according to an example of the present invention;

FIG. 7 is an illustration of arraying each file segment in a file block using the method of the present invention;

FIG. 8 illustrates an apparatus for receiving data according to an example of the present invention.

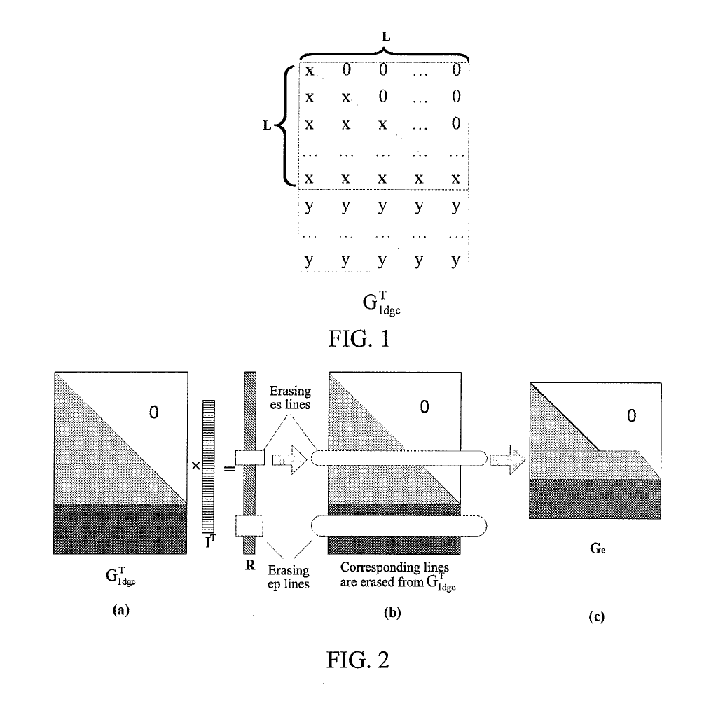

### PREFERRED EMBODIMENTS OF THE INVENTION

The main idea of the present invention is that at a data transmitting terminal: dividing data into information file segments with a fixed length, performing FEC encoding for information bit sequences composed of bits at the same position in a plurality of information file segments to generate check file segments, then encapsulating each information file segment and check file segment in a data packet for transmission; at a data receiving terminal: performing decoding for bit sequences composed of bits at the same position in a plurality of file segments to generate information file segments, then combining the information file segments in sequence according to the block numbers and segment numbers of the information file segments to generate original file data.

The data transmission method adopting the above idea, and the corresponding method and apparatus for receiving data will be further described below in detail with reference to the drawings and examples.

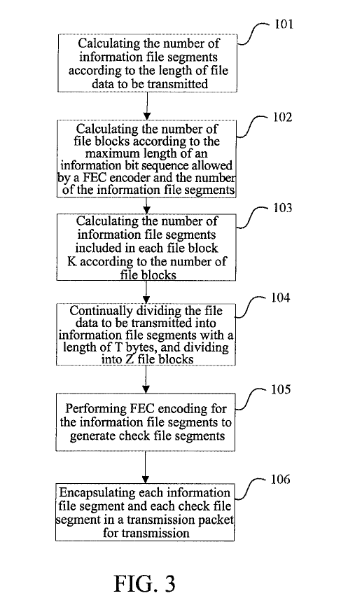

FIG. 3 illustrates the flow of a data transmission method according to an example of the present invention. As shown in FIG. 3, the method comprises the following steps:

101: calculating the number of information file segments according to the length of file data to be transmitted (also referred to as original file data);

If the length of the file data is F bytes, and the length of information file segment is T bytes, then the file data to be transmitted are divided into Kₜ=┌F/T┐ information file segments. Wherein, ┌•┐ means ceil operation.

If F/T is not an integer, then the last information file segment needs to be filled.

For example, if F=10240000 bytes, and T=512 bytes, then:

Kₜ=┌F/T┐=┌10240000/512┐=20000; i.e., the file data are divided into 20000 information file segments.

102: calculating the number of file blocks according to the maximum length of an information bit sequence allowed by a FEC encoder and the number of the information file segments;

The maximum length of an information bit sequence allowed by a FEC encoder is Kₘₐₓ, which is generally no more than 8192 bits, then the number of the file blocks is Z=┌Kₜ/Kₘₐₓ┐.

According to the above example, if Kₘₐₓ=8000 bits, then the number of file blocks divided from one file data is Z=┌Kₜ/Kₘₐₓ┐=┌20000/8000┐=3.

103: calculating the number of information file segments included in each file block K according to the number of file blocks;

File data are divided into Z=Z_{L}+Z_{S} file blocks. Wherein, in the first Z_{L} file blocks, each file block includes K=K_{L}=┌Kₜ/Z┐ information file segments, and they are called as file long blocks; in the last Z_{S} file blocks, each file block includes K=K_{S}=└Kₜ/Z┘ information file segments, and they are called as file short blocks. Wherein, └•┘ means floor operation.

The above Z_{L}, Z_{S} are calculated using the following formulas:

If K_{L}>K_{S}, then Z_{L}=(Kₜ−K_{S}×Z)/(K_{L}−K_{S}), if K_{L}=K_{S}, then K_{L}=K_{S}, then Z_{L}=Z; Z_{S}=Z−Z_{L}.

According to the above example, when Kₜ=20000:

K_{L}=┌Kₜ/Z┐=┌20000/3┐=6667 information file segments;

K_{S}=└Kₜ/Z┘=└20000/3┘=6666 information file segments;

Z_{L}=(Kₜ−K_{S}×Z)/(K_{L}−K_{S})=(20000−6666×3)/(6667−6666)=2;

Z_{S}=Z−Z_{L}=3−2=1.

In other words, each of the first two file blocks includes 6667 information file segments, and the last file block includes 6666 information file segments.

The main purpose of using the above method for assigning information file segments is to avoid the last file block from including too few information file segments. Since a corresponding number of bits are extracted from a file block for encoding according to the number of information file segments included in the file block in the subsequent steps in the present invention, the smaller the encoded code words, the worse the effect of encoding and decoding. Therefore, to avoid the file block from including too few information file segments is precisely to avoid the efficiency of encoding and decoding from being too low.

Of course, if Kₜ/Kₘₐₓ is an integer (i.e., Kₜ/Z is an integer), then each file block includes the same number of information file blocks K=Kₘₐₓ, and it is not necessary to differentiate file long block and file short blocks.

104: continually dividing the file data to be transmitted into Kₜ information file segments with a length of T bytes according to the number of information file segments Kₜ, the number of file blocks Z and the number of information file segments K included in the file block obtained through the above calculations; and grouping each information file segment in sequence, dividing the information file segments into Z file blocks.

If Kₜ/Kₘₐₓ is not an integer, the above Z file blocks include Z_{L} file long blocks and Z_{S} file short blocks. The file long blocks include K_{L} information file segments, and the file short blocks include K_{S} information file segments.

Additionally, it also needs to assign a unique File Segment Index (FSI) in the file block for each information file segment of each file block. Wherein, FSI is a positive integer.

For example, the FSI of the first information file segment of a certain file block is 0, and that of the second one is 1, and so forth.

105: performing FEC encoding for the information bit sequences composed of bits at the same position of each information file segment in each file block to generate check bit sequences; and placing each bit of the check bit sequences in the same position of check file segments in sequence;

performing FEC encoding for the information bit sequences composed of the j^{th} bit of each information file segment in each file block to generate the j^{th} check bit sequence, and placing the m^{th} bit of said check bit sequence in the j^{th} bit position of the m^{th} check file segment of the file block;

The above j=1, 2, . . . , Tb; m=1, M; M is the length of the check bit sequence.

The length of the above information bit sequence is equal to the number of the information file segments included in the file block K. That is to say: as for a file long block, the length of each information bit sequence is K_{L}; as for a file short block, the length of each information bit sequence is K_{S}.

As for different file blocks, the value of M may also be different since the length of the information bit sequence may be different.

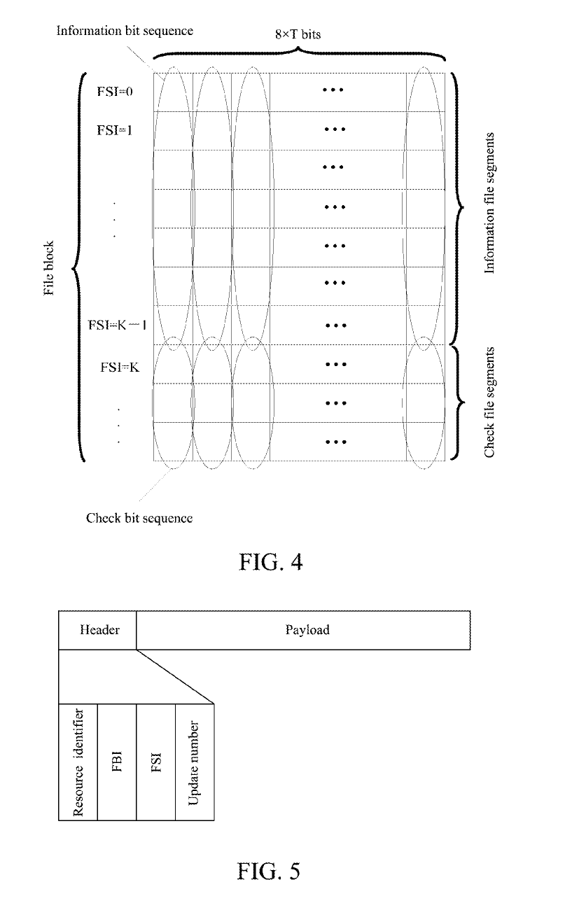

FIG. 4 is an illustration of performing FEC encoding for each information file segment in a file block by using the method of the present invention.

As shown in FIG. 4, a file block includes a plurality of information file segments and check file segments. Each information file segment includes Tb=8×T bits, and the bits at the same position of each file segment constitute an information bit sequence; FEC encoding is performed for each information bit sequence to generate a check bit sequence.

Therefore, each file block includes 8×T information bit sequences and check bit sequences. The length of an information bit sequence is K bits, and if Kₜ/Kₘₐₓ is not an integer, then K=K_{L} or K_{S}; the length of a check bit sequence is related to the length of the information bit sequence and FEC encoding algorithm.

In this example, the FEC encoding algorithm adopts system codes, for example LDGC, i.e., as for an information bit sequence with a length of K bits, the first K bits of the code word generated after encoding are the same with the information bit sequence, and the sequence composed of the subsequent bits of the code word is referred to as a check bits sequence.

In other words, one code word is composed of one information bit sequence and one check bit sequence.

106: encapsulating each information file segment and each check file segment in a transmission packet in sequence for transmission after completing encoding each bit of the information file segments of the file block.

FIG. 5 illustrates the structure of a transmission packet according to the present invention. As shown in FIG. 5, a transmission packet is composed of two parts: header (HDR) and payload.

The header includes: a resource identifier, a file block index (SBN), a file segment index (DSI) and an update serial number.

The resource identifier is used to identify the file/resource to which the data (information file segments or check file segments) transmitted in the transmission packet belong.

The file block index is used to identify the file block index of data (information file segments or check file segments) transmitted in the transmission packet.

The file segment index is the number of the information file segment or check file segment transmitted in the transmission packet.

The update number is the version number of the file/resource to which the data (information file segments or check file segments) transmitted in the transmission packet belong.

If one transmission packet includes a plurality of file segments, then the file segment index field is the FSI of the first file segment included in the transmission packet.

There are two kinds of transmission packets: information transmission packets and check transmission packets.

The payload of an information transmission packet only has information file segments; the payload of a check transmission packet only has check file segments. Therefore, the FSI of an information transmission packet should be less than K, or K_{L}, (corresponding to the file long block) or K_{S} (corresponding to the file short block); the FSI of a check transmission packet should be greater than or equal to K, or K_{L} (corresponding to the file long block) or K_{S} (corresponding to the short file block).

The payload of each transmission packet may include G file segments, and the value of G is determined through the following formula:

G=min{P/T,Gₘₐₓ};

wherein, P is the size of payload of the maximum transmission packet, Gₘₐₓ is the maximum number of file segments allowed by a transmission packet, and the length of a file segment is T bits.

For example, P=512 is the size of payload of the maximum transmission packet, Gₘₐₓ=10 is the maximum number of file segments allowed by a transmission packet. The payload of a transmission packet includes G=min{P/T, Gₘₐₓ}=min{1,10}=1 file segments.

To sum up, in the present invention, file data are divided into information file segments that are the same in volume and FEC encoding is performed on each bit at the same position of the information file segment grouped into the same file block; therefore, in the process of transmission, loss (erasion) of any information file segment only affects one bit of the code word used for decoding at the receiving terminal; meanwhile, the decoding matrix (e.g., LDGC generator matrix) used for decoding can perform the same operations such as line erasion and inversion matrix for 8×T code words, thus greatly reducing the workload of decoding at the receiving terminal. Moreover, success rate of decoding and reliability of data transmission can be significantly increased since loss of one information file segment will not cause loss (erasion) of a large amount of information of code words of at the receiving terminal.

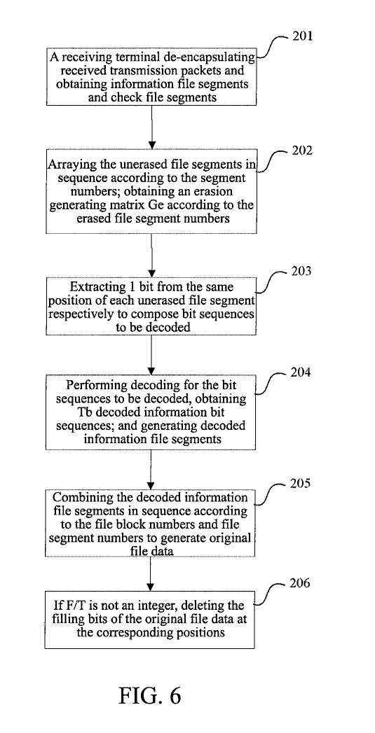

FIG. 6 illustrates a flow of a method for receiving data according to the present invention; as shown in FIG. 6, the method comprises the following steps:

201: a receiving terminal de-encapsulating received transmission packets (including: information transmission packets and check transmission packets), and obtaining each information file segment and check file segment;

The encapsulation structure of the transmission packet is as shown in FIG. 5, and the specific meaning of each field is as described above.

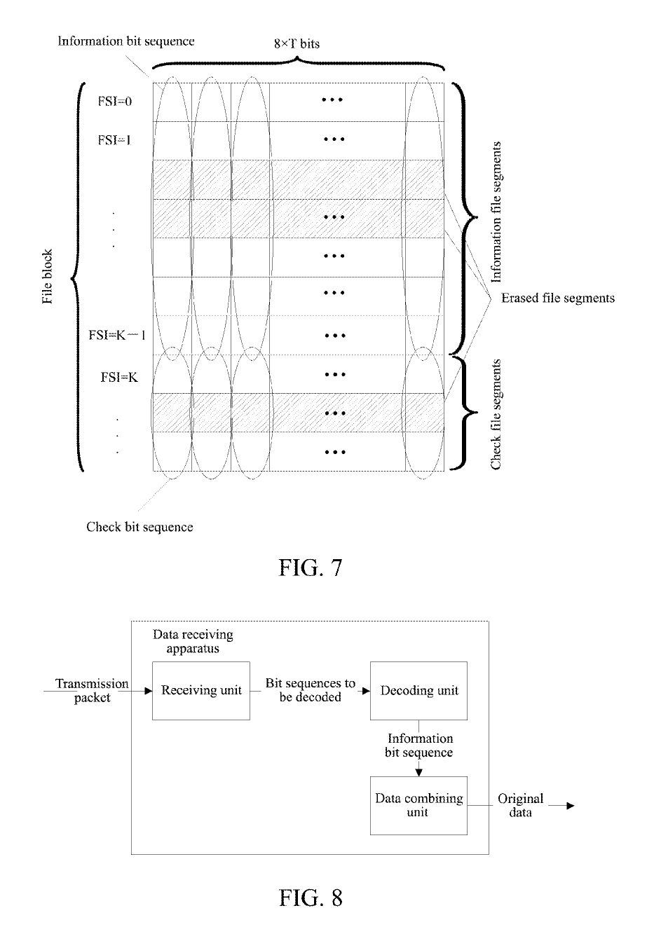

202: arraying the unerased file segments in the same file block (unerased file segments in short) in sequence according to the segment numbers, placing check file segments after information file segments, as shown in FIG. 7; meanwhile, performing erasion operation for the corresponding lines in G_{ldgc}^{T} according to the file segment indexes of the erased file segments, obtaining an erasion generator matrix Gₑ;

For example, there are N file segments in the present file block, wherein there are K information file segments, whose file segment indexes are DSI₀, DSI₁, . . . , DSI_{K} respectively; there are p (p=N−K) check file segments, whose file segment indexes are DSI_{K+1}, DSI_{K+2}, . . . , DSI_{N-1} respectively; in the process of transmission, es information file segments are erased, and their segment numbers are DSIᵤ₊₀, Dᵤ₊₁, . . . , DSIᵤ₊ₑₛ₋₁ respectively; ep check file segments are erased, and their segment numbers are DSIᵥ₊₀, DSIᵥ₊₁, . . . , DSIᵥ₊ₑₚ₋₁ respectively; then the arrayed file segments in sequence are:

DSI₀, DSI₁, . . . , Dᵤ₋₁, DSIᵤ₊ₑₛ, DSIᵤ₊ₑₛ₊₁, . . . , DSI_{K}, DSI_{K+1}, . . . , DSIᵥ₋₁, DSIᵥ₊ₑₚ, DSIᵥ₊ₑₚ₊₁, DSI_{N-1}.

203: extracting 1 bit from the same position of each unerased file segment (including information file segment and check file segment) in the same file block respectively and composing Tb=8×T bit sequences to be decoded, the length of each bit sequence to be decoded being N−es−ep;

204: performing FEC decoding for each bit sequence to be decoded using Gₑ, obtaining Tb decoded information bit sequences; and placing each bit in the decoded information bit sequences into the corresponding position of each information file segment to generate decoded information file segments;

wherein, the length of decoded information bit sequence is K, and the number of decoded information file segments is K.

For example, the bit sequence to be decoded composed of the i^{th} bit of each unerased file segment in each file block in sequence (according to the sequence of file segments) is decoded to generate the i^{th} information bit sequence, and the m^{th} bit of the information bit sequence is placed into the i^{th} bit position of the m^{th} information file segment of the decoded file block;

The above i=1, 2, . . . , Tb; m=1, 2, . . . , K; K is the length of the decoded information bit sequence.

205: combining (i.e., data combination) the decoded information file segments in sequence according to the file block indexes and file segment indexes to generate original file data (i.e., the file data transmitted by the transmitting terminal of the data);

When performing the above combination, it is preferable to array according to the file block indexes of the information file segments, and if the file block indexes are the same, then the segments are arrayed according to the file segment indexes.

206: if F/T is not an integer, and a transmitting terminal adding filling bits (i.e., filling bits in the last file segment of the last file block of the file data to be transmitted) for the file, then the receiving terminal deleting the filling bits at the corresponding positions after generator original file data.

The number of filling bits can be determined through the following method:

calculating the number of filling bits P according to the byte length F of the file data to be received and the total number Kₜ of the information file segments: P=8×(T×Kₜ−F); wherein, T is the length of each file segment, its unit being byte.

FIG. 8 illustrates an apparatus for receiving data according to an example of the present invention. As shown in FIG. 8, the apparatus comprises: a receiving unit, a decoding unit and a data combining unit. Wherein:

the receiving unit is used to receive transmission packets and obtain unerased information file segments and check file segments from the transmission packets; determine the sequence of the information file segments and check file segments according to the file segment indexes in the transmission packets; and output Tb bit sequences to be decoded of the file block;

wherein, the i^{th} bit sequence to bed ecoded is composed of the i^{th} bits of each unerased information file segment and check file segment of the file block in sequence according to the sequence of the information file segments and the check file segments; i=1, . . . , Tb.

the decoding unit is used for respectively performing forward error correction decoding for the Tb bit sequences to be decoded output by the receiving unit, outputting Tb decoded information bit sequences with a length of K of the file block;

The above forward error correction decoding can use LDGC algorithm, and the decoding unit also deletes corresponding lines of transposed G_{ldgc}^{T} of a LDGC generator matrix to generate Gₑ according to file segment indexes of erased information file segments and check file segments in the file block prior to the forward error correction decoding; and the forward error correction decoding is performed for the bit sequences to be decoded by using the Gₑ.

The data combining unit is used to extract K decoded information file segments in sequence from the Tb decoded information bit sequences of the file block with a length of K and combine them in sequence to generate original file data of the file block; additionally, the data combining unit is also used to combine the original file data of each file block in sequence according to the file block indexes to generate original file data.

Wherein the m^{th} decoded information file segment is composed of the m^{th} bits of the Tb decoded information bit sequences in sequence according to a sequence of the information bit sequences; m=1, . . . , K.

Additionally, if F/T is not an integer, then the data combining terminal also deletes P filling bits from the last file segment of the last file block;

wherein, P=8×T×Kₜ−F); F is a total byte length of the data, Kₜ=┌F/T┐, and T=Tb/8.

### INDUSTRIAL APPLICABILITY

The workload of the receiving terminal can be greatly reduced by using the data transmission method and the corresponding decoding method and apparatus of the present invention; additionally, since loss of a single data packet/information file segment does not cause loss (erasion) of a large amount of information of code words at the receiving terminal, the success rate success rate of decoding and the reliability of data transmission are dramatically improved.

What we claim is:

1. A method for receiving data, comprising a data receiving terminal processing each received file block as follows:
A: performing forward error correction decoding for Tb bit sequences to be decoded of the file block respectively, obtaining Tb decoded information bit sequences with a length of K;
wherein, the i^{th} bit sequence to be decoded is composed of the i^{th} bits of each unerased information file segment and check file segment of the file block in sequence according to a sequence of the information file segments and the check file segments;
B: combing K decoded information file segments of the file block in sequence to generate original file data of the file block;
wherein the m^{th} decoded information file segment is composed of the m^{th} bits of the Tb decoded information bit sequences in sequence according to a sequence of the information bit sequences;
i=1, . . . , Tb; m=1, . . . , K; a length of the information file segment and check file segment is Tb bits.

2. The method according to claim 1, further comprising:
the data receiving terminal obtaining the unerased information file segments and check file segments from transmission packets; the transmission packets comprising file segment indexes; a file segment index corresponding to an information file segment is lower than a file segment index corresponding to a check file segment in a same file block; and
the data receiving terminal determining the sequence of the information file segments and the check file segments according to the file segment indexes.

3. The method according to claim 2, wherein the transmission packets further comprise file block indexes;
the method further comprising the following step after completing processing of the file block:
C: the data receiving terminal combining original file data of each file block in sequence according to the file block indexes to generate the original file data.

4. The method according to claim 1, wherein if F/T is not an integer, the method further comprising:
the data receiving terminal deleting P filling bits from a last file segment of a last file block;
wherein, P=8×(T×Kₜ−F); F is a total byte length of said data, Kₜ=┌F/T┐, and T=Tb/8.

5. The method according to claim 2, wherein the forward error correction decoding uses Low Density Generator Matrix Codes (LDGC) algorithm, the method further comprising the following step before performing said forward error correction decoding:
A1: the data receiving terminal deleting corresponding lines of transposed G_{ldgc}^{T} of a LDGC generator matrix to generate Gₑ according to file segment indexes of erased information file segments and check file segments in the file block;
wherein in step A, said forward error correction decoding is performed for the bit sequences to be decoded by using the Gₑ.

6. An apparatus for receiving data, comprising a receiving unit, a decoding unit and a data combining unit; wherein:
the receiving unit is used for outputting Tb bit sequences to be decoded of a file block; wherein the i^{th} bit sequence to be decoded is composed of the i^{th} bits of each unerased information file segment and check file segment of the file block in sequence according to a sequence of the information file segments and the check file segments;
the decoding unit is used for performing forward error correction decoding for the Tb bit sequences to be decoded of the file block output by the receiving unit respectively, outputting Tb decoded information bit sequences with a length of K;
the data combining unit is used for combining K decoded information file segments of the file block in sequence to generate original file data of the file block; wherein the m^{th} decoded information file segment is composed of the m^{th} bits of the Tb decoded information bit sequences in sequence according to a sequence of the information bit sequences;
i=1, . . . , Tb; m=1, . . . , K; a length of the information file segment and check file segment is Tb bits.

7. The apparatus according to claim 6, wherein,
the receiving unit obtains the unerased information file segments and check file segments from transmission packets; the transmission packets comprise file segment indexes; a file segment index corresponding to an information file segment is lower than a file segment index corresponding to a check file segment in a same file block;
the receiving unit determines the sequence of the information file segments and the check file segments according to the file segment indexes.

8. The apparatus according to claim 7, wherein,
the transmission packets further comprise file block indexes;
the data combining unit is also used for combining original file data of each file block in sequence according to the file block indexes to generate the original file data.

9. The apparatus according to claim 6, wherein,
if F/T is not an integer, the data combining unit is also used for deleting P filling bits from a last file segment of a last file block;
wherein, P=8×(T×Kₜ−F); F is a total byte length of said data, Kₜ=┌F/T┐, and T=Tb/8.

10. The apparatus according to claim 7, wherein,
the forward error correction decoding uses Low Density Generator Matrix Codes (LDGC) algorithm;
the decoding unit also deletes corresponding lines of transposed G_{ldgc}^{T} of a LDGC generator matrix to generate Gₑ according to file segment indexes of erased information file segments and check file segments in the file block prior to performing said forward error correction decoding; and uses the Gₑ to perform said forward error correction decoding for the bit sequences to be decoded.
